(19) United States
(12) Patent Application Publication
(10) Pub. No.: US 2010/0200039 A1
(43) Pub. Date: Aug. 12, 2010

(54) Device for supplying power to field devices

(75) Inventors: Wojciech Piasecki, Krakow (PL); Robert Huber, Ketsch (DE); Marek Florkowski, Krakow (PL)

Correspondence Address: BUCHANAN, INGERSOLL & ROONEY PC, POST OFFICE BOX 1404, ALEXANDRIA, VA, 22313-1404, US

(73) Assignee: ABB AG, Mannheim (DE)

(21) Appl. No.: 12/662,170

(22) Filed: Apr. 2, 2010

Related U.S. Application Data
(62) Division of application No. 11/723,944, filed on Mar. 22, 2007.

(30) Foreign Application Priority Data
Mar. 29, 2006 (DE) 10 2006 014 444.9

(51) Int. Cl. H01L 35/30

(52) U.S. Cl. 136/205

(57) ABSTRACT

An arrangement is disclosed for supplying power to a field device used to monitor an industrial process in a plant, having an enclosure and a wireless communications interface for data communications with a central data-processing device, and having a thermoelectric converter, which converts an existing heat flow between two points at different temperatures into electrical power and supplies this power to the field device. The thermoelectric converter is arranged in a separate enclosure from the field device, and transfers the electrical power to the field device by means of electrical wires or wireless transmission.

This application is a divisional of U.S. patent application Ser. No. 11/723,944, filed on Mar. 22, 2007, which claims priority to German Application No. 10 2006 014 444.9, filed on Mar. 29, 2006, the disclosure of which is incorporated herein by reference in its entirety for all purposes.

### TECHNICAL FIELD

An arrangement for supplying power to a field device as disclosed relates to a thermoelectric converter and a field device.

### BACKGROUND INFORMATION

Field devices that are equipped with a wireless communications interface, for instance a GPRS or Bluetooth interface or another energy-saving interface such as ZigBee, are known from the prior art for use in process plants. In addition to a sensor/actuator unit, which includes the actual measurement or actuation module, a control, data-acquisition and processing module and also the wireless communications interface, these field devices also comprise inside an enclosure a power generation and supply unit for the wireless supply of power to the field device. A version of a power generation and supply unit that converts the process-related, non-electrical primary power that exists in the process plant into electrical power and in this way supplies electrical power to the field device, appears particularly advantageous here, because in this way the disadvantage of running out of power associated with conventional primary power sources such as batteries or the like is avoided. Such a system was proposed in document DE 101 20 100 A1, which employs “unconventional” primary power generators to supply field devices having a wireless communications device for use in process plants, for example by using a thermoelectric converter that converts a temperature difference between two media at different temperatures into an electric current. These thermoelectric converters make use of the Seebeck-Peltier effect to convert thermal energy into electrical energy.

Document DE 201 07 112 U1 describes a further device for supplying power to field devices in process plants, which are equipped with a wireless communications interface for communicating with a central processing device. The aforementioned thermoelectric converter is used in these field devices. The thermoelectric converter in this device is formed from a thermocouple between two sensing points, where the first sensing point projects through the wall of the pipeline of the industrial process into the process medium, and the second sensing point, located inside or outside the field device, is at the ambient temperature level in either case. In such an arrangement, however, there is the problem that the first sensing point of the thermoelectric converter, which projects into the process medium, needs to be specially protected against corrosion and contamination, which over time could impair the heat transfer from the medium to the sensor point, in particular, and hence the efficiency of the thermoelectric converter. In addition, the particular arrangement of the thermoelectric converter in this device involves a high level of design complexity.

In addition, it is known from publication WO 2004/082099 A1 to arrange the thermoelectric converter, by a converter side oriented towards the process, on the pipeline carrying process media, and to assign to the normal surroundings a second converter side oriented away from the process. The temperature difference at the two converter sides is then used by the thermoelectric converter to generate the electrical power. For this purpose, this thermoelectric converter is arranged outside the pipeline carrying process media, but inside the field device. Thus, there is a binding necessity for physically arranging the field device directly on the pipeline carrying process media. In addition, standardized field devices cannot be used because the additional thermoelectric converter is arranged in the field device.

### SUMMARY

An arrangement is disclosed for supplying power to a field device in process plants, said field device being equipped with a wireless communications interface, in which arrangement the field device can be physically arranged independently of the thermoelectric converter. In addition, the field device can also be used to monitor the physical variables present in the thermoelectric converter, and to transmit this measured data to the central data-processing device via the wireless communications interface.

An exemplary arrangement accommodates the thermoelectric converter in a separate enclosure from the field device, where the electrical power generated in the thermoelectric converter can be transferred to the field device by means of electrical wires or wireless transmission. This physical separation of the thermoelectric converter from the field device means that the field device can be arranged without physical constraints. In addition, this separation has the advantage that standardized field devices can be used. Furthermore, in such an exemplary arrangement there is no need to tap into the pipeline carrying process media, thereby avoiding the disadvantages cited for document DE 201 07 112 U1. In this arrangement, the thermoelectric converter can also be arranged in a simple manner on the pipeline, because the holder of the thermoelectric converter does not need to carry the weight of the field device as well. In addition, there is the possibility of integrating most of the thermoelectric converter in an existing insulation for the pipeline. The heat losses caused by mounting the thermoelectric converter on the pipeline can thereby be minimized. The heat lost from the pipeline carrying process media can thus be reduced virtually to the amount of heat that can be used for the electrical power conversion for the field device.

Physically separating the thermoelectric converter from the field device also delivers particular advantages when maintaining and repairing the field device. For example, the field device can be arranged simply and reversibly in the process plant. Should the field device need servicing, it can be removed without major effort because the thermal coupling required for power generation only takes place with the thermoelectric converter. The field device can also be provided at a secure location in the process plant where it is protected against potential fault situations.

In an exemplary embodiment, a thermoelectric converter is arranged adjacent to the field device on a pipeline carrying process media, where the thermoelectric converter has converter sides oriented towards the process and away from the process respectively, which form the two required points having different temperatures. Thus the actual thermoelectric converter having its converter sides oriented towards the process and away from the process respectively can constitute part of the enclosure. In addition, optimum heat transfer from the pipeline carrying process media to the thermoelectric converter is thereby possible. Advantageously, thermal conduction materials, in particular a heat transfer compound, can also be provided between the pipeline carrying process media and the converter side oriented towards the process, which can be used to optimize heat transfer. In addition, the thermoelectric converter can be provided on the converter side oriented away from the process with a heat sink having a large surface area to the surroundings. A predefined path for the heat flow in the thermoelectric converter can be created by the provided heatsink. In order that the heatsink affords good heat transfer to the surroundings of the thermoelectric converter, it can project at least partially or even completely out of the enclosure of the thermoelectric converter. This enables good heat dissipation to the surroundings of the thermoelectric converter, whereby the required temperature difference between the two points, i.e. converter sides, essential to operation can be maintained. In other words, a temperature transfer or equalization from the converter side oriented towards the process to the converter side oriented away from the process is avoided. It is thus assured that the thermoelectric converter can generate sufficient electrical power for the field device, by means of the existing temperature difference.

An exemplary embodiment provides that the existing heat flow between the converter side oriented towards the process and the converter side oriented away from the process can be converted into electrical power irrespective of the direction of heat flow. It is thereby achieved that even in situations in which, for example, the process medium in the pipeline is cooled significantly, with the process media temperature dropping below the ambient temperature, the thermoelectric converter continues to generate electrical power, and hence an uninterrupted supply of power can be provided to the field device. In addition, the range of uses of such an exemplary arrangement increases, because it does not depend on the pipeline carrying process media having to have a higher temperature than the ambient temperature.

In order to enable wireless power transmission of the generated electrical power from the thermoelectric converter to the field device, the converter can also comprise an inverter for generating an AC voltage, and a power transmit unit, in particular a coil. The generated electrical power can thereby be transmitted to the field device via induction, for example. For this purpose, the field device can similarly be equipped with a power receive unit, in particular a coil, where an additional rectifier can convert the AC voltage received from the coil into a DC voltage. Simple wireless power transmission from the thermoelectric converter to the field device can be achieved in this manner. The power receive unit together with the additional rectifier can form a further physical unit that is not provided in the enclosure of the field device. This physical unit can then in turn connect to the field device via one or more electrical wires for power transmission. It is thereby possible to revert to a standardized or existing field device despite wireless power transmission.

In another exemplary embodiment of the arrangement, it has proved practical for the thermoelectric converter to comprise at least one sensor, in particular to measure the temperature at the converter side oriented towards the process and/or away from the process, and/or the electrical variables, in particular the generated voltage and/or current. By using one or more sensors in the thermoelectric converter, it is then possible to monitor the power generation in the thermoelectric converter. The measured data produced by the sensors can be transferred to the field device e.g. via the electrical wire or the wireless power link. If an electrical wire between the thermoelectric converter and the field device is provided, an additional data line can be provided for data transmission of the measurement signals. It is also possible to transfer the measured data via the electrical wire or the wireless power transmission as modulated signals. In this version, an additional electrical data line between the thermoelectric converter and the field device is not needed.

In another exemplary embodiment of the arrangement, the field device comprises an energy storage device, in particular a battery, a storage capacitor or the like. In addition, an energy management system can be provided for the field device, where the energy management system can be integrated in a controller, or a control, data-acquisition and/or processing module. The total energy consumption of the field device can be minimized using the energy management system. The energy management system can also be connected to the central data-processing device via the wireless communications interface. If it is established, for example, that the pipeline carrying process media is not currently conveying any process medium, the power consumption of the field device can be reduced via the central data-processing device by setting the field device to a “stand-by” state until the process medium is again being conveyed through the pipeline. Possible fluctuations in power from the thermoelectric converter can be smoothed out by the optional use of the energy storage device. Depending on the size of the energy storage device, the field device can thus also be run temporarily without power from the thermoelectric converter.

Measured data from the additional sensors can also be sent from the thermoelectric converter to the field device. In this case, the field-device electronic circuitry can also capture this measured data and transmit it with the other data to the central data-processing device via the wireless communications interface. Convenient diagnosis of the field device and/or the thermoelectric converter is also possible by this means. In addition, potential signal drop-outs from the field device can be identified in advance, for example should the power from the thermoelectric converter no longer be sufficient to supply the field device.

For this purpose, the field-device electronic circuitry can also comprise a diagnostic function, whereby the measured data from the thermoelectric converter can be monitored, and warning messages on the status of the thermoelectric converter generated by the diagnostic function can be transmitted to the central data-processing device via the wireless communications interface.

### BRIEF DESCRIPTION OF THE DRAWINGS

Additional measures and advantages of the invention follow from the claims, the following description and the drawings. The invention is shown schematically in two exemplary embodiments in the drawings, in which

FIG. 1 shows a schematic diagram of a first exemplary embodiment, having a thermoelectric converter, which supplies via an electrical wire the power for the physically separate field device, and

FIG. 2 shows a schematic diagram of a second exemplary embodiment, in which the electrical power from the thermoelectric converter can be transmitted wirelessly to the field device.

### DETAILED DESCRIPTION

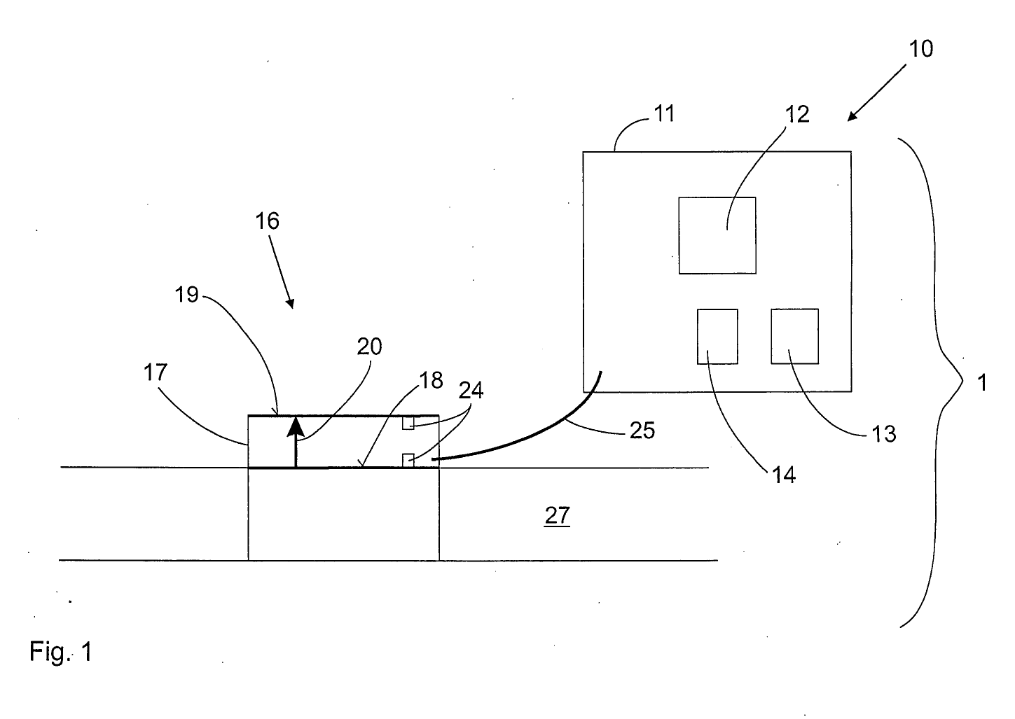

FIG. 1 shows an exemplary arrangement 1 for supplying power to a field device 10 having an enclosure 11 and a wireless communications interface 13 for data communications with a central data-processing device. A thermoelectric converter 16 is also provided in a separate enclosure 17 for supplying power to the field device 10. This thermoelectric converter converts an existing heat flow 20 between two points 18, 19 at different temperatures into electrical power and supplies this generated electrical power to the field device 10 via one or more electrical wires 25. The thermoelectric converter 16 is itself arranged by means of a holder on a pipeline 27 carrying process media, for example, with a converter side 18 oriented towards the process resting directly or indirectly on the pipeline 27 carrying process media. The temperature of the pipeline 27 is thereby to be transferred to the converter side 18 oriented towards the process. Thermal conduction materials can be provided for this purpose between the pipeline 27 and the converter side 18 oriented towards the process. In addition, the thermoelectric converter 16 comprises a converter side 19, which is normally oriented away from the converter side 18 oriented towards the process, and which can be realized by an enclosure side of the enclosure 17. The two converter sides 18, 19 can constitute the two required points 18, 19 between which there can be a temperature difference. The heat flow 20 that exists between the converter sides 18, 19 can be converted into electrical power by the thermoelectric converter 16. This heat flow 20 is shown schematically in FIG. 1 by the arrow 20.

Various sensors 24 can be provided in order also to measure the active physical and/or electrical variables of the thermoelectric converter 16. In the present example, a sensor 24 can be arranged on each of the converter sides 18, 19 oriented towards the process and away from the process respectively. These sensors 24 measure the respective temperature at the converter sides 18, 19, and can transfer the measured data to the field device 10, in particular to the field-device electronic circuitry 12, for example via the electrical wire 25. The field-device electronic circuitry 12 advantageously has a diagnostic function for the measured data from the thermoelectric converter 16. This measured data as well can thus be monitored by the field device 10 in order to transmit to the central data-processing device via the wireless communications interface 13, the warning messages on the current status of the thermoelectric converter 16 obtained by the diagnosis, for example. Any malfunctions caused by an intermittent power supply to the field device 10 can hence be predicted in advance. Such malfunctions could occur, for example, if there should no longer be a temperature difference at the two points 18, 19 in the thermoelectric converter 16. This could happen, for example, if no further process medium were transported through the pipeline 27 for a prolonged period. In order to attenuate or absorb any fluctuations in the power supply, the field device 10 can be provided with an additional energy storage device 14. This energy storage device 14 can not only attenuate power fluctuations from the thermoelectric converter 16, but can also ensure to some extent operation without any external power. In addition, it can be practical for the field device 10 to be equipped with an energy management system, where the energy management system can be integrated in the field-device electronic circuitry 12.

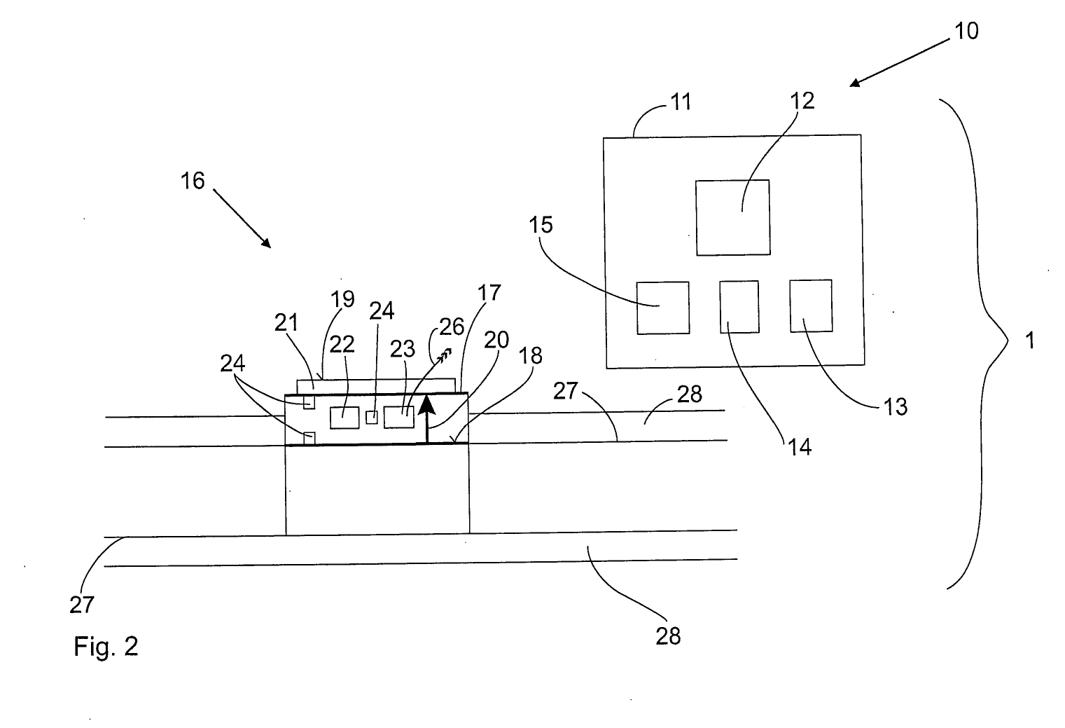

In both FIGS. 1 and 2, the electrical connections inside the thermoelectric converter 16 and the field device 10 have not been shown, to improve clarity.

In FIG. 2, a further exemplary embodiment of the arrangement 1 is shown as arranged. This arrangement 1 also contains a field device 10 supplied with power by a thermoelectric converter 16. Unlike the first exemplary embodiment, however, this power is not transmitted by a wire 25, but the power can be transmitted wirelessly. The thermoelectric converter 16 comprises in its enclosure 17 an inverter 22 for this purpose, which converts the electrical power obtained into an AC voltage. This AC voltage can then be transmitted wirelessly to the field device 10 via a power transmit unit 23 comprising a coil, for example. The field device comprises a power receive unit 15 for this purpose, which may also comprise a coil. It is thereby possible to operate the field device 10 close to the thermoelectric converter 16 without any physical connection. Thus precisely in extremely difficult conditions of use of the field device 10, it is possible to decouple the thermoelectric converter 16 totally from the field device 10. As shown in the illustrated exemplary embodiment, the thermoelectric converter 16 can be arranged by means of a holder inside an insulation 28 around the pipeline 27 carrying process media. In this case it can be sufficient if just the converter side 19 oriented away from the process, i.e. the second point 19, of the thermoelectric converter 16 projects out of the insulation 28 so that it is exposed to the surroundings. As a practical addition here, the thermoelectric converter 16 can also comprise a heatsink 21 on its converter side 19 oriented away from the process, in order to avoid heating or cooling by the converter side 18 oriented towards the process. The additional heatsink 21 is intended to achieve as large a temperature difference as possible between the converter sides 18, 19 oriented towards the process and away from the process respectively. In order to obtain as detailed information as possible on the current status of the thermoelectric converter 16, additional sensors 24 can be provided for measuring the respective temperature at the converter sides 18, 19. Likewise it is conceivable to measure via the sensors 24 also the electrical voltage and the electrical current of the generated power from the thermoelectric converter 16. The data provided by the sensors 24 can be transmitted to the field device 10 with the generated power. Standard data transmission techniques can be used in this case. The actual power transmission is indicated by the arrow 26 in FIG. 2.

The field device 10 provided in the exemplary arrangement 1 accommodates inside the enclosure 11 the field-device electronic circuitry 12 and the communications interface 13. In addition, the power receive unit 15 for wireless power transmission 26 can be provided and an additional energy storage device 14 and/or rectifier can optionally be present. Likewise in this embodiment as well, the field-device electronic circuitry 12 can be used for capturing and monitoring the measured data supplied by the sensors 24 from the thermoelectric converter 16. As in the first exemplary embodiment, a diagnosis can then be performed on the received measured data from the thermoelectric converter 16.

Finally it should be mentioned that any combination of the described technical features from the two exemplary embodiments is also possible unless explicitly ruled out.

It will be appreciated by those skilled in the art that the present invention can be embodied in other specific forms without departing from the spirit or essential characteristics thereof. The presently disclosed embodiments are therefore considered in all respects to be illustrative and not restricted. The scope of the invention is indicated by the appended claims rather than the foregoing description and all changes that come within the meaning and range and equivalence thereof are intended to be embraced therein.

### LIST OF REFERENCES

1 arrangement
10 field device
11 enclosure
12 field-device electronic circuitry
13 communications interface
14 energy storage device
15 power receive unit
16 thermoelectric converter
17 enclosure
18 converter side oriented towards the process/1st point
19 converter side oriented away from the process/2nd point
20 arrow for heat flow
21 heatsink
22 inverter
23 power transmit unit
24 sensor
25 electrical wire
26 arrow for wireless power transmission
27 pipeline carrying process media
28 insulation

What is claimed is:

1. An arrangement for supplying power to a field device used to monitor an industrial process in a plant, the field device having an enclosure and a wireless communications interface for data communications with a central data-processing device, the arrangement comprising:
a thermoelectric converter for converting a heat flow between two points at different temperatures into electrical power and for supplying the electrical power to the field device,
wherein the thermoelectric converter is arranged in a separate enclosure from the field device and configured to wirelessly transfer the electrical power to the field device.

2. The arrangement as claimed in claim 1, wherein the thermoelectric converter is configured to be arranged on a pipeline carrying process media, where, when arranged on the pipeline, sides of the thermoelectric converter oriented towards the process media and away from the process media respectively form the two points having different temperatures.

3. The arrangement as claimed in claim 2, wherein the heat flow between the converter sides oriented towards the process media and away from the process media, respectively, is converted by the thermoelectric converter into electrical power irrespective of the direction of heat flow.

4. The arrangement as claimed in claim 1, wherein the thermoelectric converter is provided with a heatsink on a converter side oriented away from the process media.

5. The arrangement as claimed in claim 4, wherein the heatsink projects at least partially out of the thermoelectric converter enclosure.

6. The arrangement as claimed in claim 1, wherein the thermoelectric converter comprises:
an inverter for generating an AC voltage; and
a power unit configured to wirelessly transmit the electrical power to the field device.

7. The arrangement as claimed in claim 1, wherein the thermoelectric converter comprises:
at least one sensor configured to measure the temperature at the converter sides, and/or electrical variables as a measurement signal for transfer to the field device.

8. The arrangement as claimed in claim 1, further comprising the field device, wherein the field device comprises:
a power receive unit for receiving a wireless power transmission including the electric power from the thermoelectric converter, the power receive unit including a rectifier configured to generate a DC voltage from the wireless power transmission.

9. The arrangement as claimed in claim 1, further comprising the field device, wherein the field device comprises:
an energy storage device and/or an energy management system, where the energy management system is integrated in one of a controller and a control, data-acquisition and/or processing module.

10. The arrangement as claimed in claim 1, further comprising the field device, wherein the field-device comprises circuitry configured to capture measured data from the thermoelectric converter,
wherein the circuitry is configured to transmit measured to the central data-processing device via the wireless communications interface.

11. The arrangement as claimed in claim 10, further comprising the field device, wherein the circuitry of the field-device comprises:
a diagnostic function, whereby measured data from the thermoelectric converter are monitored, and warning messages on the status of thermoelectric converter generated by the diagnostic function are transmitted to the central data-processing device via the wireless communications interface.

12. A field device comprising:
circuitry for wirelessly receiving power from a thermoelectric converter which converts a heat flow between two points at different temperatures into electrical power, and which wirelessly supplies the electric power to the field device; and
an enclosure arranged separate from an enclosure of the for the thermoelectric converter.

13. The arrangement as claimed in claim 3, wherein the thermoelectric converter comprises:
a heatsink on the converter side oriented away from the process media.

14. The arrangement as claimed in claim 5, wherein the thermoelectric converter comprises:
an inverter for generating an AC voltage; and
a power transmit unit configured to wirelessly transmit the electrical power to the field device.

15. The arrangement as claimed in claim 6, wherein the thermoelectric converter comprises:
at least one sensor configured to measure the temperature at the converter sides oriented towards the process media and/or away from the process media, and/or the electrical variables, where the corresponding measurement signal can be transferred to the field device.

16. The arrangement as claimed in claim 7, further comprising the field device wherein the field device comprises:
a power receive unit for receiving a wireless power transmission including the electric power from the thermoelectric converter, the power receive unit including a rectifier configured to generate a DC voltage from the wireless power transmission.

17. The arrangement as claimed in claim 8, wherein the field device comprises:
an energy storage device, and/or an energy management system, where the energy management system can be integrated in a controller, or a control, data-acquisition and/or processing module.

18. The arrangement as claimed in claim 9′, wherein the field-device comprises circuitry configured to capture measured data from the thermoelectric converter,
wherein the circuitry is configured to transmit the measured data to the central data-processing device via the wireless communications interface.

19. An arrangement for supplying power to a field device used to monitor an industrial process in a plant, comprising:
a field device containing a communications interface for data communications regarding a process variable;
a thermoelectric converter for monitoring the process variable and for wirelessly supplying electrical power to the field device; and
an field device enclosure, and a thermoelectric converter enclosure to separate the thermoelectric converter from the field device.
